(19) United States
(12) Patent Application Publication
(10) Pub. No.: US 2019/0273101 A1
(43) Pub. Date: Sep. 5, 2019

(54) SEMICONDUCTOR DEVICE AND DISPLAY UNIT

(71) Applicant: JOLED INC., Tokyo (JP)

(72) Inventor: Tomoatsu Kinoshita, Tokyo (JP)

(21) Appl. No.: 16/289,659

(22) Filed: Mar. 1, 2019

(30) Foreign Application Priority Data
Mar. 5, 2018 (JP) 2018-038373

(51) Int. Cl. H01L 27/12; H01L 29/66; H01L 29/786

(52) U.S. Cl. CPC H01L 27/1251; H01L 27/1222; H01L 29/7869; H01L 29/6675; H01L 29/78603; H01L 27/1262

(57) ABSTRACT

A semiconductor device includes a substrate, a transistor, an electrically-conductive film, and a voltage applying section. The substrate includes a resin material and has a first surface and a second surface opposite to each other. The transistor is provided on the first surface of the substrate, and includes a semiconductor layer and paired source-drain electrodes. The source-drain electrodes are electrically coupled to the semiconductor layer, and are configured to receive a source potential and a drain potential, respectively. The electrically-conductive film is provided on the second surface of the substrate. The voltage applying section is configured to supply the electrically-conductive film with any of a potential equal to the source potential, a potential equal to the drain potential, and a potential between the source potential and the drain potential.

### CROSS REFERENCE TO RELATED APPLICATIONS

This application claims the benefit of Japanese Priority Patent Application No. 2018-038373 filed on Mar. 5, 2018, the entire contents of which are incorporated herein by reference.

### BACKGROUND

The technology relates to a semiconductor device that includes a transistor on a substrate, and a display unit that includes the semiconductor device.

A thin-film transistor (TFT) has found its application in a variety of electronic apparatuses. Reference is made to Japanese Unexamined Patent Application Publication No. 2017-49568, for example. The thin-film transistor is provided on a substrate, for example.

### SUMMARY

It is desired for a semiconductor device that includes a transistor on a substrate to suppress a decrease in reliability of the transistor.

It is desirable to provide a semiconductor device that makes it possible to suppress a decrease in reliability of a transistor, and a display unit that includes such a semiconductor device.

According to one embodiment of the technology, there is provided a semiconductor device including: a substrate including a resin material and having a first surface and a second surface, the first surface and the second surface being opposite to each other; a transistor provided on the first surface of the substrate and including a semiconductor layer and paired source-drain electrodes, the source-drain electrodes being electrically coupled to the semiconductor layer and being configured to receive a source potential and a drain potential, respectively; an electrically-conductive film provided on the second surface of the substrate; and a voltage applying section configured to supply the electrically-conductive film with any of a potential equal to the source potential, a potential equal to the drain potential, and a potential between the source potential and the drain potential.

According to one embodiment of the technology, there is provided a display unit including: a substrate including a resin material and having a first surface and a second surface, the first surface and the second surface being opposite to each other; a transistor provided on the first surface of the substrate and including a semiconductor layer and paired source-drain electrodes, the source-drain electrodes being electrically coupled to the semiconductor layer and being configured to receive a source potential and a drain potential, respectively; an electrically-conductive film provided on the second surface of the substrate; a voltage applying section configured to supply the electrically-conductive film with any of a potential equal to the source potential, a potential equal to the drain potential, and a potential between the source potential and the drain potential; and a display device layer including a plurality of pixels and provided on the first surface of the substrate with the transistor being provided between the display device layer and the first surface of the substrate.

### BRIEF DESCRIPTION OF THE DRAWINGS

The accompanying drawings are included to provide a further understanding of the technology and are incorporated in and constitute a part of this specification. The drawings illustrate example embodiments and, together with the specification, serve to explain the principles of the technology.

FIG. 1 is a schematic cross-sectional view of a display unit having an example outline configuration according to one example embodiment of the technology.

FIG. 2 is a block diagram illustrating the entire configuration of the display unit illustrated in FIG. 1.

FIG. 3 is a schematic view of a semiconductor device having an outline configuration according to Comparative Example 1.

FIG. 4 is a schematic diagram illustrating an electric filed applied on a substrate illustrated in FIG. 3.

FIG. 5 is a schematic cross-sectional view of a semiconductor device having an outline configuration according to Comparative Example 2.

FIG. 6 is a schematic diagram illustrating an electric field applied on a substrate illustrated in FIG. 1.

FIG. 7 is a graph illustrating an example relation between a magnitude of a potential supplied to an electrically-conductive film illustrated in FIG. 1 and a variation in threshold voltage of a TFT.

FIG. 8 is a block diagram illustrating an example configuration of a display unit according to one example embodiment of the technology.

FIG. 9 is a block diagram illustrating an example configuration of an imaging unit according to one example embodiment of the technology.

FIG. 10 is a block diagram illustrating an example configuration of an electronic apparatus according to one example embodiment of the technology.

### DETAILED DESCRIPTION

In the following, some example embodiments of the technology are described in detail, in the following order, with reference to the accompanying drawings. Note that the following description is directed to illustrative examples of the technology and not to be construed as limiting to the technology. Factors including, without limitation, numerical values, shapes, materials, components, positions of the components, and how the components are coupled to each other are illustrative only and not to be construed as limiting to the technology. Further, elements in the following example embodiments which are not recited in a most-generic independent claim of the technology are optional and may be provided on an as-needed basis. The drawings are schematic and are not intended to be drawn to scale. Note that the like elements are denoted with the same reference numerals, and any redundant description thereof will not be described in detail. Note that the description is given in the following order.

### 1. Embodiments (Example Display Unit Including Voltage Applying Section Coupled to Electrically-conductive Film)

### 2. Example Configuration of Display Unit

3. Example Imaging unit

### 4. Example Electronic Apparatus

### EMBODIMENTS

### [Configuration]

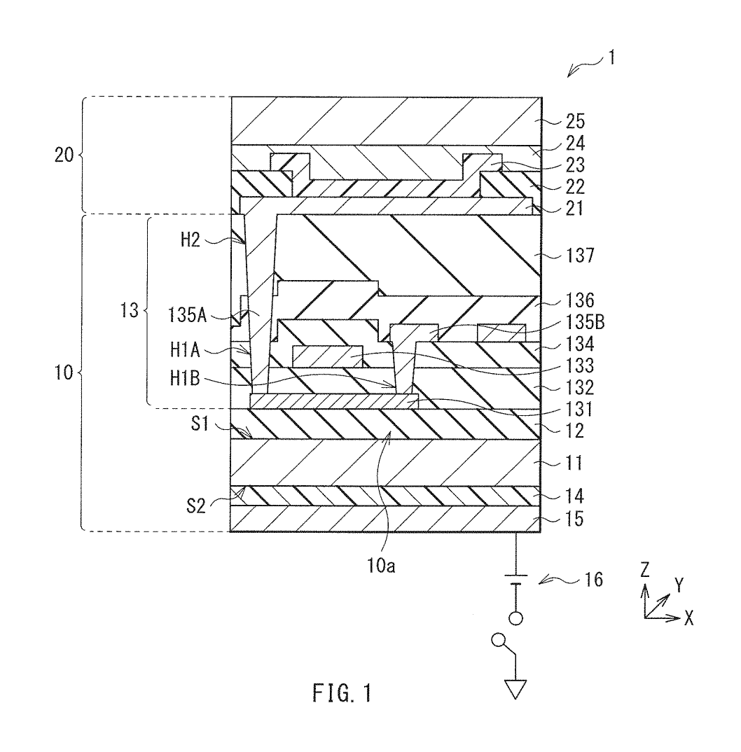

FIG. 1 schematically illustrates a cross-sectional configuration of a display unit 1 according to an example embodiment of the technology. The display unit 1 may be an organic electroluminescent (EL) unit, for example, and may include a semiconductor device 10 and a display device layer 20 on the semiconductor device 10. The semiconductor device 10 may include a plurality of TFTs 10a. The display device layer 20 may include a plurality of organic electroluminescent elements 20A. Note that FIG. 1 illustrates one of the TFTs 10a and one of the organic electroluminescent elements 20A.

The semiconductor device 10 may include an undercoat film 12 and a TFT layer 13 in this order on a front surface S1 of a substrate 11. Note that the front surface S may correspond to a specific but non-limiting example of “first surface” according to an example embodiment of the technology. The TFT layer 13 may include the TFT 10a. An electrically-conductive film 15 may be attached to a rear surface S2 of the substrate 11 through an adhesive layer 14. The rear surface S2 may be opposite to the front surface S1 of the substrate 11 and may correspond to a specific but non-limiting example of “second surface” according to one embodiment of the technology.

The substrate 11 may be a flexible substrate, for example. The substrate 11 includes a resin material, and may have a thickness within a range from 5 μm to 40 μm along a Z axis of FIG. 1, for example. Specific but non-limiting examples of the resin material included in the substrate 11 may include polyethylene terephthalate (PET), polyimide (PI), polycarbonate (PC), polyamide, polyethersulfone (PES), and polyethylene naphthalate (PEN). In one example, the substrate 11 may include PI. The substrate 11 that includes PI may exhibit improved thermal resistance, which may increase a processing temperature during manufacture of the TFT layer 13.

The UC film 12 may suppress or prevent substances such as sodium ions from migrating from the substrate 11 to an upper layer. The UC film 12 may include an insulating material, such as silicon nitride (SiN) or an oxide silicon (SiO). Alternatively, the UC film 12 may be a laminate that includes a silicon nitride (SiN) film and an oxide silicon (SiO) film in this order from the substrate 11. The UC film 12 may extend over the entire surface of the substrate 11.

The TFT 10a in the TFT layer 13 may be a top-gate thin-film transistor, for example, and may have a semiconductor layer 131 in a selective region on the UC film 12. A gate insulating film 132 may be provided on the semiconductor layer 131, and a gate electrode 133 may be provided on the gate insulating film 132. An interlayer insulating film 134 may cover the gate electrode 133. The interlayer insulating film 134 and the gate insulating film 132 may have respective contact holes H1A and H1B. Each of the contact holes H1A and H1B may be opposed to a portion of the semiconductor layer 131. Paired source-drain electrodes 135A and 135B may be provided on the interlayer insulating film 134 so as to fill the contact holes H1A and H1B, respectively. The interlayer insulating film 134 and the source-drain electrodes 135A and 135B may be covered with a passivation film 136. A planarization film 137 may be provided between the passivation film 136 and a first electrode 21 (described below) of the display device layer 20. The TFT 10a may correspond to a specific but a non-limiting example of “transistor” according to one embodiment of the technology.

The semiconductor layer 131 may be formed on the UC film 12 by patterning. The semiconductor layer 131 may include a channel region serving as an active layer in a region opposed to the gate electrode 133. The semiconductor layer 131 may include an oxide semiconductor that mainly but not necessarily mainly includes an oxide of one or more elements of indium (In), gallium (Ga), zinc (Zn), tin (Sn), titanium (Ti), and niobium (Nb), for example. Specific but non-limiting example of the oxide semiconductor included in the semiconductor layer 131 may include indium tin zinc oxide (ITZO), indium gallium zinc oxide (IGZO: InGaZnO), zinc oxide (ZnO), indium zinc oxide (IZO), indium gallium oxide (IGO), indium tin oxide (ITO), and indium oxide (InO). Alternatively, the semiconductor layer 131 may include low-temperature polycrystalline silicon (LTPS) or amorphous silicon (a-Si), for example.

The gate insulating film 132 may be a single-layer film that include one of oxide of silicon oxide (SiOₓ), silicon nitride (SiNₓ), silicon nitride oxide (SiON), and aluminum oxide (AlOₓ), for example. Alternatively, the gate insulating film 132 may be a multi-layer film that includes two or more of these oxides. For example, the gate insulating film 132 may cover the semiconductor layer 131 and extend over the entire surface of the substrate 11. The gate insulating film 132 may be provided on the channel region of the semiconductor layer 131, and may have a shape similar to or the same as the shape of the gate electrode 133.

The gate electrode 133 may control a carrier density in the semiconductor layer 131 on the basis of a gate voltage (Vg) applied thereto, and may serve as a wiring line that supplies a potential. The gate electrode 133 may include a material that contains one of metal elements of titanium (Ti), tungsten (W), tantalum (Ta), aluminum (Al), molybdenum (Mo), silver (Ag), neodymium (Nd), and copper (Cu), or an alloy thereof, for example. Alternatively, the gate electrode 133 may include a compound that contains one or more these metal elements or may be a multi-layer film that contains two or more these metal elements. Still alternatively, the gate electrode 133 may be a film that includes a transparent electrically conductive material, such as ITO.

The interlayer insulating film 134 may include, for example, an organic material, such as acrylic resin, polyimide (PI), or novolak resin. Alternatively, the interlayer insulating film 134 may include an inorganic material, such as silicon oxide, silicon nitride, silicon oxide nitride, or aluminum oxide.

The source-drain electrodes 135A and 135B may respectively serve as a source and a drain of the TFT 10a, and may include one of the metals or the transparent electrically conductive materials that are described above as the materials for the gate electrode 133. In one example, the source-drain electrodes 135A and 135B may include a material having high electrical conductivity. For example, the source-drain electrode 135A may serve as the source of the TFT 10a, and the source-drain electrode 135B may serve as the drain of the TFT 10a. In this example, the source-drain electrode 135A may be supplied with a source potential PS, and the source-drain electrode 135B may be supplied with a drain potential PD.

The passivation film 136 may extend over the interlayer insulating film 134 so as to cover the source-drain electrodes 135A and 135B. The passivation film 136 may include oxide silicon (SiO) or silicon nitride (SiN), for example. The planarization film 137 may cover the TFT 10a with the passivation film 136 provided therebetween.

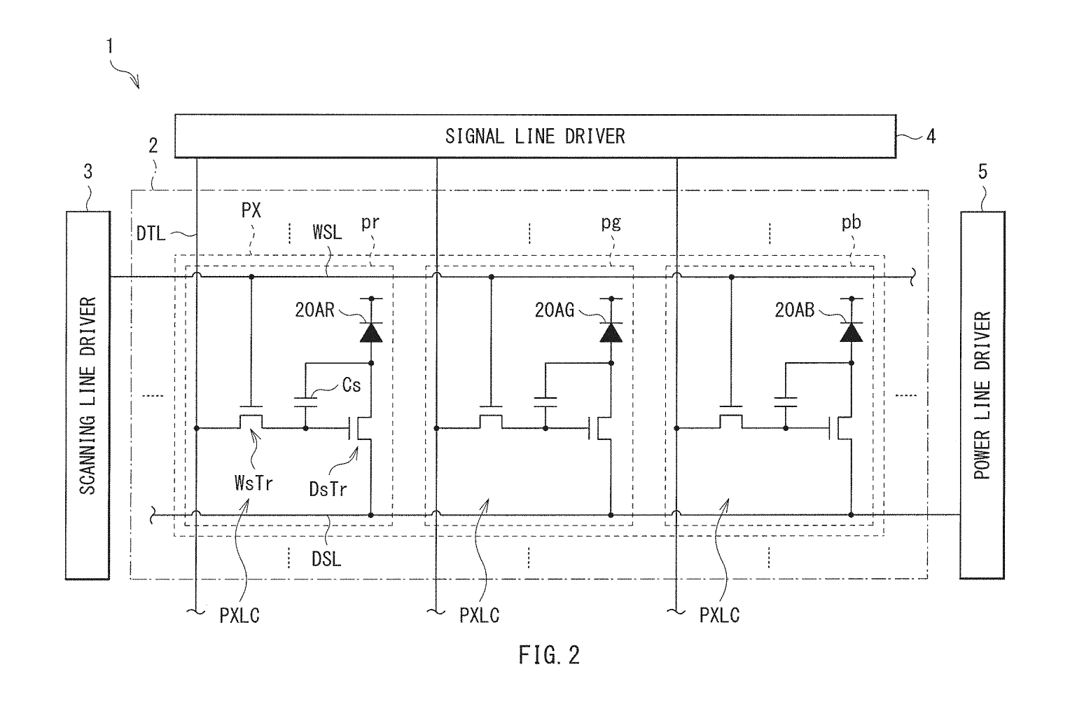

The display device layer 20 provided on the planarization film 137 may include a plurality of pixels (e.g., pixels pr, pg, and pb illustrated in FIG. 2 described below) and an organic electroluminescent element 20A. The organic electroluminescent element 20A may be driven by a backplane provided with the plurality of TFTs 10a to thereby perform image displaying. The organic electroluminescent element 20A may include, for example, a first electrode 21, an organic layer 23 that includes a light-emitting layer, and a second electrode 24, in this order from the TFT layer 13. The first electrode 21 may serve as an anode, for example, and may be coupled to the source-drain electrode 135A of the TFT 10a. The second electrode 24 may serve as a cathode, for example. The second electrode 24 may receive a cathode potential through a common potential line, such as a cathode line, for example. The cathode potential may be common between the pixels. A partition 22 may be provided between the first electrode 21 and the organic layer 23. The second electrode 24 may be covered with a protection film 25.

The first electrode 21 may be provided in a selective region on the planarization film 137 in each pixel, for example. The first electrode 21 may inject holes to the light-emitting layer of the organic layer 23, for example. The first electrode 21 may include, for example, an electrically-conductive material having light reflectivity. For example, the first electrode 21 may include a single metal element, such as silver (Ag) or aluminum (Al), or an alloy thereof. The first electrode 21 may be electrically coupled to the source-drain electrode 135A through a contact hole H2. The contact hole H2 may extend through the planarization film 137 and the passivation film 136, for example.

The partition 22 may be provided between each two of the first electrodes 21 adjacent to each other, and may cover end portions of the first electrodes 21. The partition 22 may electrically separate the first electrodes 21 in the respective pixels from one another to ensure insulation between each of the first electrodes 21 and corresponding one of the second electrodes 24. The partition 22 may include acrylic resin or polyimide resin, for example.

The organic layer 23 provided between the first electrode 21 and the second electrode 24 has the light-emitting layer that includes an organic compound. The organic layer 23 may include a layer emitting red light, a layer emitting green light, and a layer emitting blue light in each of the pixels. The light-emitting layer may generate excitons through recombination of holes and electrons injected from the first electrode 21 and the second electrode 24, respectively, to thereby emit light. Optionally, the organic layer 23 may include a hole transport layer and a hole injection layer between the light-emitting layer and the first electrode 21, and/or may include an electron transport layer and an electron injection layer between the light-emitting layer and the second electrode 24.

The second electrode 24 may be opposed to the first electrode 21 across the organic layer 23. The second electrode 24 may extend over the entire surface of a pixel section 2 illustrated in FIG. 2 described below, and may be shared across the pixels. The second electrode 24 may inject electrons to the light-emitting layer of the organic layer 23. The second electrode 24 may include, for example, an electrically-conductive material having light transmissivity. For example, the second electrode 24 may be a film that includes a transparent electrically conductive material, such as indium tin oxide (ITO), indium zinc oxide (IZO), or indium gallium zinc oxide (IGZO).

The protection film 25 covering the second electrode 24 may include, for example, an inorganic material, such as silicon nitride or silicon oxide.

The electrically-conductive film 15 may be attached to the rear surface S2 of the substrate 11 through the adhesive layer 14. The electrically-conductive film 15 may be opposed to the substrate 11, and may have a shape substantially the same as the shape of the substrate 11. In the present example embodiment, the electrically-conductive film 15 may be electrically coupled to the voltage applying section 16. Upon driving of the TFT 10a, the voltage applying section 16 supplies the electrically-conductive film 15 with a potential P15 that is any of a potential equal to the source potential PS, a potential equal to the drain potential PD, and a potential between the source potential PS and the drain potential PD. This makes the substrate 11 that includes a resin material less likely to generate an electric charge, which is described in detail below. Accordingly, it is possible to suppress a decrease in the reliability of the TFT 10a.

The electrically-conductive film 15 may include a metal material, such as iron (Fe), aluminum (Al), or nickel (Ni). The electrically-conductive film 15 may have a thickness within a range from 1 μm to 200 μm, for example. Alternatively, the electrically-conductive film 15 may include an electrically-conductive material other than the metal material. In one example, the electrically-conductive film 15 may protect and reinforce the substrate 11. The adhesive layer 14 provided between the electrically-conductive film 15 and the substrate 11 may have electrical conductivity. The adhesive layer 14 may include, for example, a resin material, such as acrylic or urethane, in which electrically-conductive metal particles are dispersed. Such an adhesive layer 14 having electrical conductivity may further reduce an electric field F1 (illustrated in FIG. 6 described below) applied to the substrate 11. Alternatively, the adhesive layer 14 may be insulative.

The voltage applying section 16 may include a DC power source, for example. When the drain potential PD is higher than the source potential PS, the potential P15 supplied from the voltage applying section 16 to the electrically-conductive film 15 may satisfy the relation PS≤P15≤PD. In an example where the TFT 10a is a driving transistor DsTr illustrated in FIG. 2 described below, the first electrode 21 may be supplied with a potential equal to the source potential PS. While the TFT 10a is not driven, the voltage applying section 16 may be coupled to a ground (GND) potential.

FIG. 2 is a block diagram illustrating the entire configuration of the display unit 1. The display unit 1 may include a pixel section 2 and circuitry that drives the pixel section 2. The pixel section 2 may include the pixels pr, pg, and pb, that are arranged in a two-dimensional matrix. The circuitry may include a scanning line driver 3, a signal line driver 4, and a power line driver 5. In the display unit 1, red light, green light, and blue light may be respectively extracted from the pixel pr, pg and pb, for example.

The pixel section 2 may be driven by an active matrix scheme, for example, and may display an image on the basis of an external image signal. The pixel section 2 may include a plurality of scanning lines WSL extending in a row direction, a plurality of signal lines DTL extending in a column direction, and a plurality of power lines DSL extending in the row direction. The row direction and the column direction may be along each pixel array. These scanning line WSL, the signal line DTL, and the power line DSL may be electrically coupled to a corresponding one of the pixels pr, pg, or pb. The pixels pr, pg, and pb may each correspond to a subpixel, and may together serve as a single pixel PX.

The pixel pr may include an organic electroluminescent element 20AR emitting red light, for example. The pixel pg may include an organic electroluminescent element 20AG emitting green light, for example. The pixel pb may include an organic electroluminescent element 20AB emitting blue light, for example. In the following description, the pixels pr, pg, and pb are collectively referred to as “pixel P” in cases where no distinction is needed among the pixels pr, pg, and pb. Likewise, the organic electroluminescent elements 20AR, 20AG, and 20AB are hereinafter collectively referred to as “organic electroluminescent element 20A” in cases where no distinction is needed among the organic electroluminescent elements 20AR, 20AG, and 20AB.

The scanning lines WSL may supply the respective pixels P with a selection pulse to select the pixels P in the pixel section 2 on a row basis. The scanning lines WSL may be coupled to a non-illustrated output terminal of the scanning line driver 3 and a gate electrode of a switching transistor WsTr described below. The signal lines DTL may supply a signal pulse to the respective pixels P. The signal pulse may have a signal potential Vsig and a reference potential Vofs in accordance with the image signal. The signal lines DTL may be coupled to a non-illustrated output terminal of the signal line driver 4 and a source electrode or a drain electrode of the switching transistor WsTr described below. The power lines DSL may supply the respective pixels P with a fixed potential Vcc as electric power. The power lines DSL may be coupled to a non-illustrated output terminal of the power line driver 5 and a source electrode or a drain electrode of the driving transistor DsTr described below. The cathode (i.e., the second electrode 24) of the organic electroluminescent element 20A may be coupled to the common potential line (i.e., the cathode line).

The scanning line driver 3 may output a predetermined selection pulse to the respective scanning lines WSL in a line sequential manner to cause the pixels P to perform various operations, such as anode resetting, threshold voltage (Vth) compensation, writing of the signal voltage Vsig, mobility compensation, and light emission, at a predetermined timing. The signal line driver 4 may generate an analog image signal based on an external digital signal, and may transmit the analog image signal to the respective signal lines DTL. The power line driver 5 may output a constant potential to the power lines DSL. The scanning line driver 3, the signal line driver 4, and the power line driver 5 may operate in conjunction with one another in response to a timing signal from a non-illustrated timing controller. The external digital image signal may be corrected at a non-illustrated image signal receiver and thereafter transferred to the signal line driver 4.

The semiconductor device 10 may include a pixel circuit PXLC that drives the organic electroluminescent element 20A. The pixel circuit PXLC may control light emission and light extinction of the organic electroluminescent elements 20A. The pixel circuit PXLC may include, for example, any one of the organic electroluminescent elements 20AR, 20AG, and 20AB, and may further include a storage capacitor Cs, the switching transistor WsTr, and the driving transistor DsTr.

The switching transistor WsTr may control application of an image signal (signal voltage) to the gate electrode of the driving transistor DsTr. For example, the switching transistor WsTr may sample a signal voltage of the signal line DTL on the basis of a voltage applied to the scanning line WSL, and may write the sampled signal voltage to the gate electrode of the driving transistor DsTr. The driving transistor DsTr may be coupled in series to the organic electroluminescent element 20A. The driving transistor DsTr may regulate an electric current flowing in the organic electroluminescent element 20A on the basis of the magnitude of the signal voltage sampled at the switching transistor WsTr. The driving transistor DsTr and the switching transistor WsTr may be, for example, thin-film transistors (TFTs) of an n-channel MOS type or a p-channel MOS type. Additionally, the driving transistor DsTr and the switching transistor WsTr may be of a single-gate type or a dual-gate type. The storage capacitor Cs may hold a predetermined voltage between the gate electrode and the source electrode of the driving transistor DsTr.

The gate electrode of the switching transistor WsTr may be coupled to the scanning line WSL. One of the source electrode and the drain electrode of the switching transistor WsTr may be coupled to the signal line DTL. The other of the source electrode and the drain electrode of the switching transistor WsTr may be coupled to the gate electrode of the driving transistor DsTr. One of the source electrode and the drain electrode of the driving transistor DsTr may be coupled to the power line DSL. The other of the source electrode and the drain electrode of the driving transistor DsTr may be coupled to the anode (i.e., the first electrode 21) of the organic electroluminescent element 20A. The storage capacitor Cs may be disposed between the gate electrode of the driving transistor DsTr and the other of the source electrode and the drain electrode of the driving transistor DsTr coupled to the anode of the organic electroluminescent element 20A.

Although the TFT 10a is not illustrated in FIG. 2, the driving transistor DsTr may include the TFT 10a, for example. Alternatively, the switching transistor WsTr may include the TFT 10a.

Note that the pixel circuit PXLC may have, for example but not limited to, a 2Tr1C circuit configuration in any foregoing example embodiment of the technology. Alternatively, the pixel circuit PXLC may have a configuration including various capacitors and transistors in addition to the 2Tr1C configuration.

### Example Workings and Effects

In the display unit 1 according to any foregoing example embodiment of the technology, each of the pixels pr, pg, and pb in the display device layer 20 may be driven to perform image displaying on the basis of an external image signal. In the foregoing example embodiment, the TFTs 10a in the pixels pr, pg, and pb may be each driven by a voltage in the TFT layer 13 of the semiconductor device 10. For example, when a voltage equal to or higher than a threshold voltage is applied to the gate electrode 133 of the TFT 10a in any one of the pixels pr, pg, and pb, the semiconductor layer 131 may be activated (i.e., a channel may be formed) to cause an electric current flow between the paired source-drain electrodes 135A and 135B.

In the semiconductor device 10 according to any foregoing example embodiment of the technology, the voltage applying section 16 supplies the electrically-conductive film 15 with the potential P15. The potential P15 is any of a potential equal to the source potential PS, a potential equal to the drain potential PD, and a potential between the source potential PS and the drain potential PD. This reduces an electric field (e.g., electric field F1 illustrated in FIG. 6 described below) applied to the substrate 11, making the substrate 11 that includes a resin material less likely to generate an electric charge. Accordingly, it is possible to suppress a decrease in the reliability of TFT 10a. These example workings and effects will now be described with reference to comparative examples.

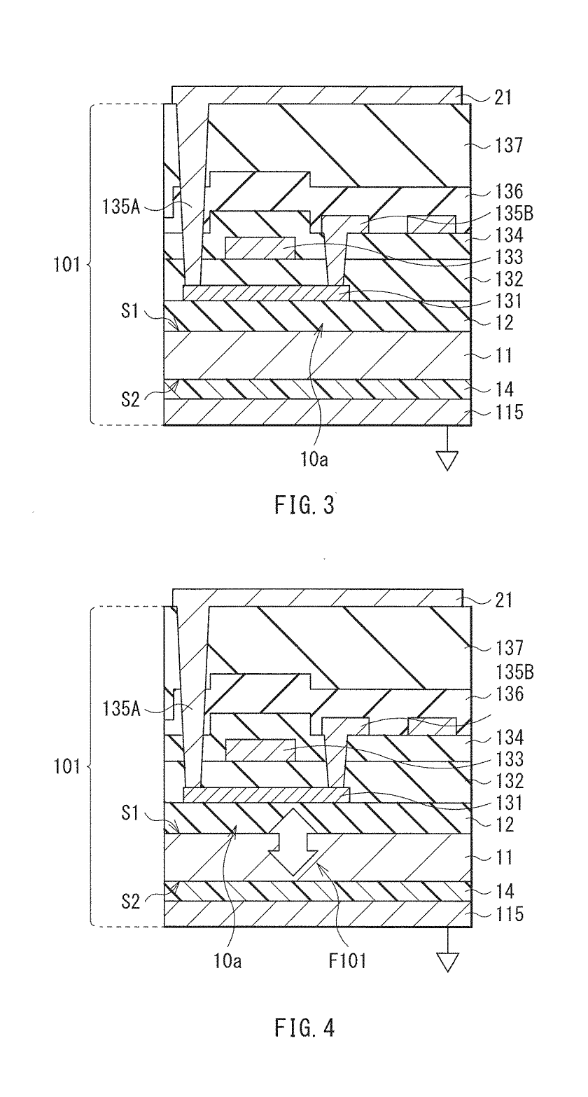

FIG. 3 illustrates a schematic cross-sectional configuration of a semiconductor device 101 according to Comparative Example 1. In the semiconductor device 101, an electrically-conductive film 115 is attached to the rear surface S2 of the substrate 11. The electrically-conductive film 115 protects and reinforces the flexible substrate 11. The electrically-conductive film 115 is coupled to a ground potential.

FIG. 4 illustrates an electric field F101 applied to the substrate 11 upon driving of the TFT 10a of the semiconductor device 101. In the semiconductor device 101, the source-drain electrode 135A is supplied with the source potential PS, and the source-drain electrode 135B is supplied with the drain potential PD, upon the driving of TFT 10a. In this situation, the electrically-conductive film 115 may have a ground potential of 0 volts, and a potential difference between the TFT 10a (i.e., the semiconductor layer 131) and the electrically-conductive film 115 may increase. Accordingly, the electric field F101 applied to the substrate 11 becomes large. The substrate 11 that includes a resin material is more likely to generate an electric charge than a substrate that includes a glass material. Such a large electric charge generated in the substrate 11 can cause a variation in a characteristic of the TFT 10a, impairing the reliability of the TFT 10a. Note that specific but non-limiting examples of the characteristic of the TFT 10a may include a threshold voltage of the TFT 10a, for example.

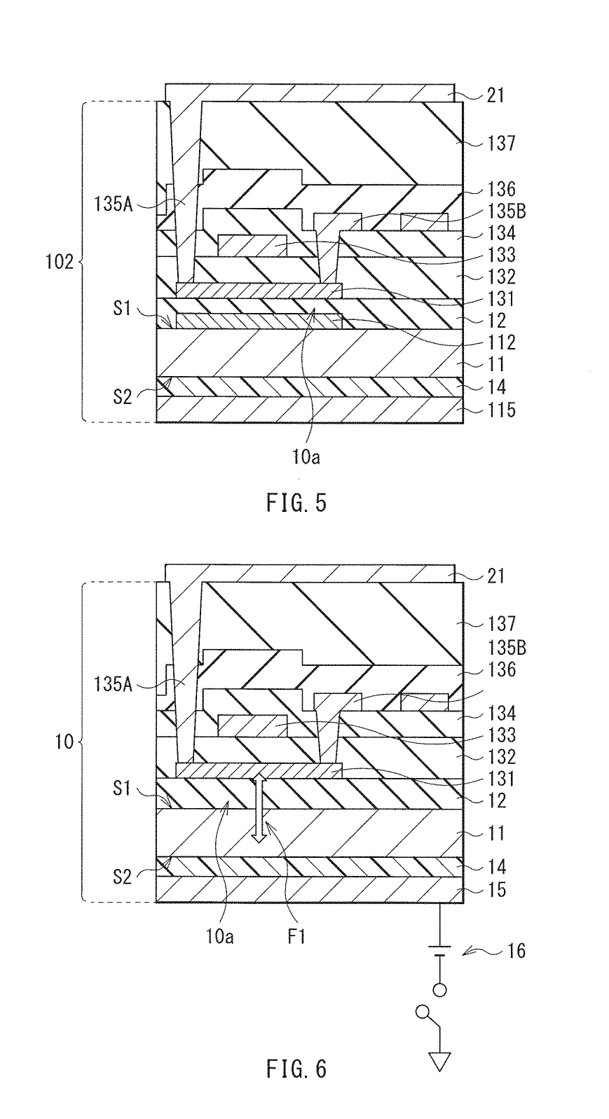

FIG. 5 schematically illustrates a cross-sectional configuration of a semiconductor device 102 according to Comparative Example 2. The semiconductor device 102 includes an electric field shielding layer 112 between the substrate 11 and the semiconductor layer 131. The electric field shielding layer 112 may include an electrically-conductive metal film, for example. The electric field shielding layer 112 helps to reduce an electric field applied to the substrate 11. The electric field shielding layer 112, however, causes a parasitic capacitance between the electric field shielding layer 112 and the TFT 10a or other wiring lines. Additionally, the electric field shielding layer 112 increases a manufacturing cost of the semiconductor device 102 and also generates the need for an additional process of manufacturing the electric field shielding layer 112. This results in an increase in the number of processes to be performed, which, in turn, results in a reduction in yield.

In contrast, in the semiconductor device 10 according to the example embodiment of the technology, the electrically-conductive film 15 may be supplied with the potential P15 so that the potential difference between the TFT 10a (i.e., the semiconductor layer 131) and the electrically-conductive film 15 becomes small, unlike in the semiconductor device 101.

FIG. 6 illustrates an electric field F1 applied to the substrate 11 upon the driving of the TFT 10a of the semiconductor device 10. When the electrically-conductive film 15 is supplied with the potential P15, the electric field F1 applied to the substrate 11 becomes smaller than the electric field F101 (F1<F101). This makes the substrate 11 less likely to generate an electric charge than the semiconductor device 101 is, and suppresses a variation in the characteristic, such as a threshold voltage, of the TFT 10a.

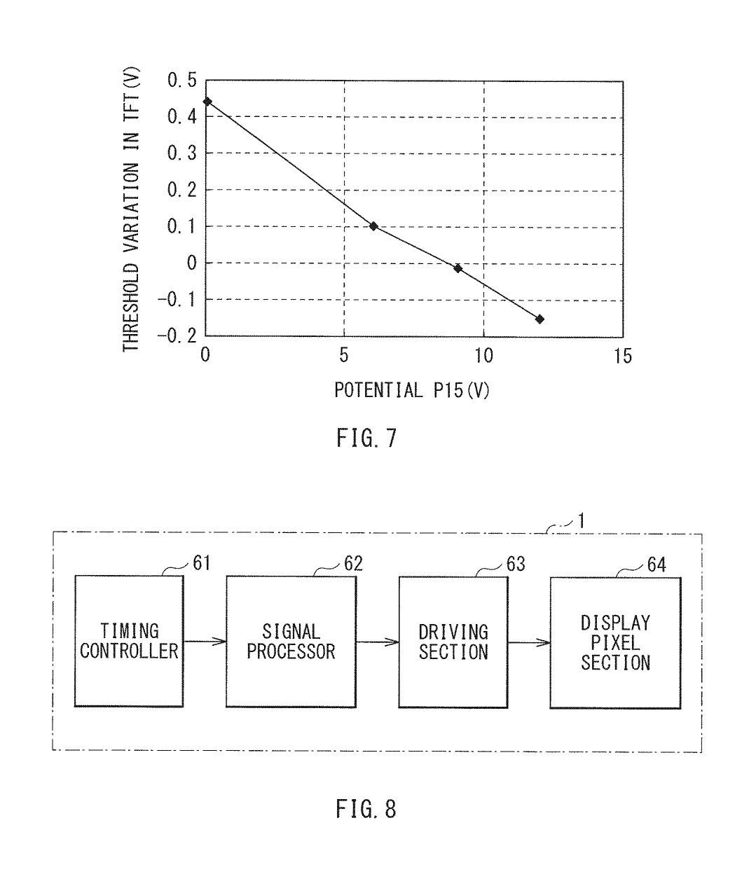

FIG. 7 illustrates an example relation between the level of the potential P15 supplied to the electrically-conductive film 15 and a variation of the threshold voltage of the TFT 10a. In this experiment, the source potential PS was 7 volts, and the drain potential PD was 16 volts. It was confirmed from the result of the experiment that the variation in the threshold voltage of the TFT 10a became smaller when the relation PS≤P15≤PD was satisfied than when the potential P15 was 0 volts.

As described above, in the semiconductor device 10 according to any foregoing example embodiment of the technology, the voltage applying section 16 supplies the electrically-conductive film 15 with the potential P15. This reduces the electric field F1 applied to the substrate 11, and suppresses the characteristic variation of the TFT 10a, unlike the semiconductor device 101.

Furthermore, the semiconductor device 10 eliminates the need for the electric field shielding layer 112 illustrated in FIG. 5. This suppresses or prevents a parasitic capacitance, an increase in costs, and a reduction in yield caused by the electric field shielding layer 112.

In any foregoing example embodiment of the technology as described above, the electrically-conductive film 15 is supplied with the potential P15 that is any of a potential equal to the source potential PS, a potential equal to the drain potential PD, and a potential between the source potential PS and the drain potential PD. This suppresses the characteristic variation of the TFT 10a caused by the electric charge generated in the substrate 11. Accordingly, it is possible to suppress a decrease in the reliability of the TFT 10a.

Furthermore, the electric field shielding layer is not needed in any foregoing example embodiment of the technology. This prevents a parasitic capacitance, an increase in costs, and a reduction in yield caused by the electric field shielding layer.

### Example Configuration of Display Unit

FIG. 8 is a block diagram of the display unit 1 according to the foregoing example embodiment of the technology.

The display unit 1 may display an external or internal image signal in the form of an image. The display unit 1 may be applied to, for example, a liquid crystal display as well as the organic EL display described above. The display unit 1 may include, for example, a timing controller 61, a signal processor 62, a driving section 63, and a display pixel section 64.

The timing controller 61 may include a timing generator that generates various timing signals or control signals. The timing controller 61 may control driving of the signal processor 62 or any other component on the basis of the various timing signals. The signal processor 62 may perform a predetermined correction of an external digital image signal, for example, and may output the corrected image signal to the driving section 63. The driving section 63 may include a scanning line driving circuit and a signal line driving circuit, for example, and may drive pixels in the display pixel section 64 through various control lines. The display pixel section 64 may include, for example, a display element (e.g., the display device layer 20 described above), such as an organic electroluminescent element or a liquid crystal display element, and a pixel circuit that drives the display element on a pixel basis. The TFT 10a described above may be used in any circuit serving as a portion of the driving section 63 or a portion of the display pixel section 64.

### Example Imaging Unit

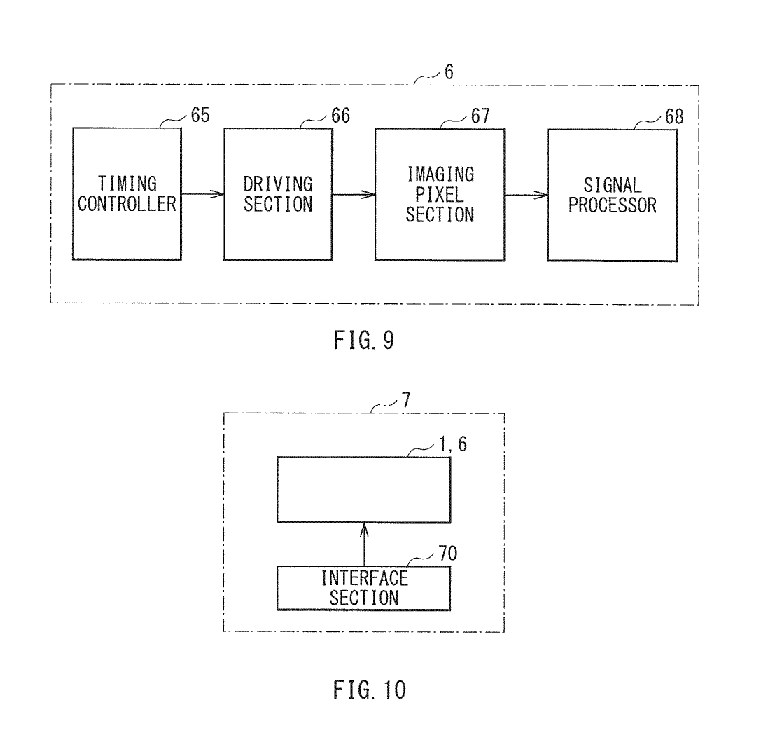

In the foregoing embodiment of the technology, the semiconductor device 10 may be applied to the display unit 1. Additionally, the semiconductor device 10 may be applied to an imaging unit 6 illustrated in FIG. 9, as well as the display unit 1.

The imaging unit 6 may be a solid imaging unit that acquires an image in the form of an electric signal, for example. The imaging unit 6 may include, for example, a charge coupled device (CCD) or a complementary metal oxide semiconductor (CMOS) image sensor. The imaging unit 6 may include, for example, a timing controller 65, a driving section 66, an imaging pixel section 67, and a signal processor 68.

The timing controller 65 may include a timing generator that generates various timing signals or control signals. The timing controller 65 may control driving of the driving section 66 on the basis of the various timing signals. The driving section 66 may include a row selection circuit, an AD converter circuit, and a horizontal transfer scanning circuit, for example. The driving section 66 may read a signal from each pixel in the imaging pixel section 67 through various control lines. The imaging pixel section 67 may include, for example, an imaging element, such as a photoelectric transducer or a photodiode, and a pixel circuit that reads signals. The signal processor 68 may perform various processes to the signals received from the imaging pixel section 67. The TFT 10a described above may be used in various circuits that serve as a portion of the driving section 66 or a portion of the imaging pixel section 67, for example.

### Example Electric Apparatus

The display unit 1 and the imaging unit 6 according to any foregoing example embodiment of the technology may be applied to a variety of electronic apparatuses. FIG. 10 is a block diagram of an electronic apparatus 7. Specific but non-limiting examples of the electronic apparatus 7 may include television apparatuses, personal computers (PCs), smartphones, tablet PCs, mobile phones, digital still camaras, and digital video cameras.

The electronic apparatus 7 may include, for example, the display unit 1 or the imaging unit 6 according to any foregoing example embodiment of the technology, and an interface section 70. The interface section 70 may be an input section that receives various external signals and electric power. The interface section 70 may include a user interface, such as a touch panel, a keyboard, and operational buttons.

Although the technology is described with reference to the example embodiments and application examples hereinabove, these example embodiments and application examples are not to be construed as limiting the scope of the technology and may be modified in a wide variety of ways. For example, the materials and thicknesses of the layers described in the example embodiments should not be limited to those described above, and may be different from those described above.

Although the TFT 10a may have a top-gate structure in the foregoing example embodiment of the technology, the foregoing example embodiment of the technology may also be applicable to a semiconductor device that includes the TFT 10a having a bottom-gate structure.

Although the TFT 10a may serve as the driving transistor DsTr in the foregoing example embodiment of the technology, the TFT 10a may serve as another component other than the driving transistor DsTr.

It should be appreciated that the effects described herein are mere examples. Effects of the example embodiment of the technology are not limited to those described herein, and may be different from those described herein. The technology may further include any effects other than those described herein.

It is possible to achieve at least the following configurations from the foregoing example embodiments and application examples of the technology.

(1) A semiconductor device including:
a substrate including a resin material and having a first surface and a second surface, the first surface and the second surface being opposite to each other;
a transistor provided on the first surface of the substrate and including a semiconductor layer and paired source-drain electrodes, the source-drain electrodes being electrically coupled to the semiconductor layer and being configured to receive a source potential and a drain potential, respectively;
an electrically-conductive film provided on the second surface of the substrate; and
a voltage applying section configured to supply the electrically-conductive film with any of a potential equal to the source potential, a potential equal to the drain potential, and a potential between the source potential and the drain potential.
   (2) The semiconductor device according to (1), further including an adhesive layer between the substrate and the electrically-conductive film, in which
the electrically-conductive film is attached to the second surface of the substrate through the adhesive layer.
   (3) The semiconductor device according to (2), in which the adhesive layer has electrical conductivity.
   (4) The semiconductor device according to any one of (1) to (3), in which
the transistor further includes a gate electrode and a gate insulating film, the gate electrode being opposed to the semiconductor layer, the gate insulating film being provided between the gate electrode and the semiconductor layer.
   (5) The semiconductor device according to any one of (1) to (4), in which the resin material includes polyimide.
   (6) The semiconductor device according to any one of (1) to (5), in which the electrically-conductive film includes a metal material.
   (7) The semiconductor device according to any one of (1) to (6), in which the voltage applying section is connectable to a ground potential.
   (8) A display unit including:
a substrate including a resin material and having a first surface and a second surface, the first surface and the second surface being opposite to each other;
a transistor provided on the first surface of the substrate and including a semiconductor layer and paired source-drain electrodes, the source-drain electrodes being electrically coupled to the semiconductor layer and being configured to receive a source potential and a drain potential, respectively;
an electrically-conductive film provided on the second surface of the substrate;
a voltage applying section configured to supply the electrically-conductive film with any of a potential equal to the source potential, a potential equal to the drain potential, and a potential between the source potential and the drain potential; and
a display device layer including a plurality of pixels and provided over the first surface of the substrate with the transistor being provided between the display device layer and the first surface of the substrate.
   (9) The display unit according to (8), in which the display device layer includes a first electrode, a second electrode, and an organic layer, the first electrode and the second electrode being opposite to each other, the organic layer being provided between the first electrode and the second electrode.
   (10) The display unit according to (9), in which one of the paired source-drain electrodes is electrically coupled to the first electrode.

In the semiconductor device and the display unit according to any foregoing example embodiment of the technology, the electrically-conductive film is supplied with any of a potential equal to the source potential, a potential equal to the drain potential, and a potential between the source potential and the drain potential. This makes the substrate less likely to generate an electric charge.

In the semiconductor device and the display unit according to any foregoing example embodiment of the technology, the electrically-conductive film is supplied with any of a potential equal to the source potential, a potential equal to the drain potential, and a potential between the source potential and the drain potential. This suppresses a characteristic variation of the transistor caused by an electric charge generated in the substrate. Accordingly, it is possible to suppress a decrease in reliability of the transistor. It should be understood that effects of the example embodiments and application examples of the technology are not limited to those described hereinabove, and may be any effect described herein.

Although the technology is described hereinabove in terms of example embodiments and application examples, it is not limited thereto. It should be appreciated that variations may be made in the example embodiments and the application examples described herein by persons skilled in the art without departing from the scope of the technology as defined by the following claims. The limitations in the claims are to be interpreted broadly based on the language employed in the claims and not limited to examples described in this specification or during the prosecution of the application, and the examples are to be construed as non-exclusive. For example, in this technology, the use of the terms first, second, etc. do not denote any order or importance, but rather the terms first, second, etc., are used to distinguish one element from another. The term “disposed on/provided on/formed on” and its variants as used herein refer to elements disposed directly in contact with each other or indirectly by having intervening structures therebetween. Moreover, no element or component in this technology is intended to be dedicated to the public regardless of whether the element or component is explicitly recited in the following claims.

What is claimed is:

1. A semiconductor device comprising:
a substrate including a resin material and having a first surface and a second surface, the first surface and the second surface being opposite to each other;
a transistor provided on the first surface of the substrate and including a semiconductor layer and paired source-drain electrodes, the source-drain electrodes being electrically coupled to the semiconductor layer and being configured to receive a source potential and a drain potential, respectively;
an electrically-conductive film provided on the second surface of the substrate; and
a voltage applying section configured to supply the electrically-conductive film with any of a potential equal to the source potential, a potential equal to the drain potential, and a potential between the source potential and the drain potential.

2. The semiconductor device according to claim 1, further comprising an adhesive layer between the substrate and the electrically-conductive film, wherein
the electrically-conductive film is attached to the second surface of the substrate through the adhesive layer.

3. The semiconductor device according to claim 2, wherein the adhesive layer has electrical conductivity.

4. The semiconductor device according to claim 1, wherein
the transistor further includes a gate electrode and a gate insulating film, the gate electrode being opposed to the semiconductor layer, the gate insulating film being provided between the gate electrode and the semiconductor layer.

5. The semiconductor device according to claim 1, wherein the resin material includes polyimide.

6. The semiconductor device according to claim 1, wherein the electrically-conductive film includes a metal material.

7. The semiconductor device according to claim 1, wherein the voltage applying section is connectable to a ground potential.

8. A display unit comprising:
a substrate including a resin material and having a first surface and a second surface, the first surface and the second surface being opposite to each other;
a transistor provided on the first surface of the substrate and including a semiconductor layer and paired source-drain electrodes, the source-drain electrodes being electrically coupled to the semiconductor layer and being configured to receive a source potential and a drain potential, respectively;
an electrically-conductive film provided on the second surface of the substrate;
a voltage applying section configured to supply the electrically-conductive film with any of a potential equal to the source potential, a potential equal to the drain potential, and a potential between the source potential and the drain potential; and
a display device layer including a plurality of pixels and provided over the first surface of the substrate with the transistor being provided between the display device layer and the first surface of the substrate.

9. The display unit according to claim 8, wherein the display device layer includes a first electrode, a second electrode, and an organic layer, the first electrode and the second electrode being opposite to each other, the organic layer being provided between the first electrode and the second electrode.

10. The display unit according to claim 9, wherein one of the paired source-drain electrodes is electrically coupled to the first electrode.
